(19) United States
(12) Patent Application Publication
(10) Pub. No.: US 2025/0272002 A1
(43) Pub. Date: Aug. 28, 2025

(54) CONTROLLER, MEMORY DEVICE, AND ELECTRONIC DEVICE

(71) Applicant: SK hynix Inc., Gyeonggi-do (KR)

(72) Inventors: Hyeong Ju NA, Gyeonggi-do (KR); Ie Ryung PARK, Gyeonggi-do (KR)

(21) Appl. No.: 19/033,402

(22) Filed: Jan. 21, 2025

(30) Foreign Application Priority Data
Feb. 28, 2024 (KR) 10-2024-0028831

(51) Int. Cl. G06F 3/06

(52) U.S. Cl. CPC G06F 3/0619; G06F 3/0659; G06F 3/0673

(57) ABSTRACT

Embodiments of the present disclosure update a level value indicating a read voltage according to a fail bit detected during a read operation for a memory and provide the updated level value to the memory before transmitting a read command to allow a read operation to be performed according to the read voltage indicated by the updated level value, thereby enhancing the accuracy of the read operation through a read operation suitable for the characteristics for each storage area of the memory and enhancing the operation performance and reliability of the memory.

### CROSS-REFERENCES TO RELATED APPLICATION

The present application claims priority under 35 U.S.C. 119(a) to Korean patent application number 10-2024-0028831 filed on Feb. 28, 2024, which is incorporated herein by reference in its entirety.

### TECHNICAL FIELD

Embodiments of the present disclosure relate to a controller, a memory device, and an electronic device.

### BACKGROUND

A storage device may include at least one memory storing data. The storage device may include a controller that controls the operation of at least one memory in some cases.

The memory may include a plurality of memory cells and store data using the plurality of memory cells.

To increase memory capacity and enhance performance, the size of each of the plurality of memory cells may be gradually reduced. As the size of the memory cell decreases, the possibility of errors occurring when writing data to the memory cell or reading data written to the memory cell may increase.

### SUMMARY

Embodiments of the present disclosure may provide a method for reducing the size of a plurality of memory cells included in a memory, reducing the occurrence of errors during a data processing operation for the memory, and enhancing the operation performance of the memory.

Embodiments of the present disclosure may provide an electronic device comprising at least one memory including a plurality of bank groups, and a controller configured to update a history table including a level value indicating a read voltage for a read operation on the plurality of bank groups based on fail bit information according to an error correction operation for data read from the at least one memory and transmit the level value included in the updated history table to the at least one memory.

Embodiments of the present disclosure may provide a memory device comprising a first bank group including at least one first bank including a plurality of first memory cells, a second bank group including at least one second bank including a plurality of second memory cells, at least one voltage regulating circuit configured to output a read voltage to at least one of the first bank group or the second bank group, and a control circuit configured to receive a first command including a level value from an outside during a first period, receive a second command indicating a read operation during a second period, and adjust the read voltage output by the at least one voltage regulating circuit based on the level value.

Embodiments of the present disclosure may provide a controller comprising an internal memory storing a history table, an error correction circuit configured to perform an error correction operation for data read from an external memory, and a history table managing circuit configured to update the history table including a level value indicating a read voltage for a read operation for the external memory based on fail bit information according to the error correction operation, and transmit the level value included in the updated history table to the external memory.

According to embodiments of the present disclosure, there may be provided a method for reducing performance deterioration due to error occurrence during a memory operation and preventing error occurrence from increasing with memory use.

### BRIEF DESCRIPTION OF THE DRAWINGS

FIG. 1 is a view illustrating a schematic configuration of a storage device according to embodiments of the present disclosure;

FIG. 2 is a view illustrating a schematic configuration of a memory according to embodiments of the present disclosure;

FIG. 3 is a view illustrating a schematic configuration of a controller according to embodiments of the present disclosure;

FIG. 4 is a view illustrating an operation method of a controller according to embodiments of the present disclosure;

FIG. 5 is a view illustrating a configuration for controlling a read voltage in a memory according to embodiments of the present disclosure;

FIG. 6 is a view illustrating an operation method of a control circuit included in the memory of FIG. 5;

FIG. 7 is a view illustrating an operation method of a voltage regulating circuit included in the memory of FIG. 5;

FIG. 8 is a view illustrating a refresh operation of the memory of FIG. 5; and

FIGS. 9 and 10 are flowcharts illustrating a process of an operation method of a controller according to embodiments of the present disclosure.

### DETAIL DESCRIPTION

In the following description of embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of embodiments of the present disclosure, detailed descriptions of well-known functions and components incorporated herein will be omitted when it is determined that the description may make the subject matter in some embodiments of this disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of this disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all meanings of the term “can”.

Hereinafter, various embodiments of the present disclosure will be described in detail with reference to accompanying drawings.

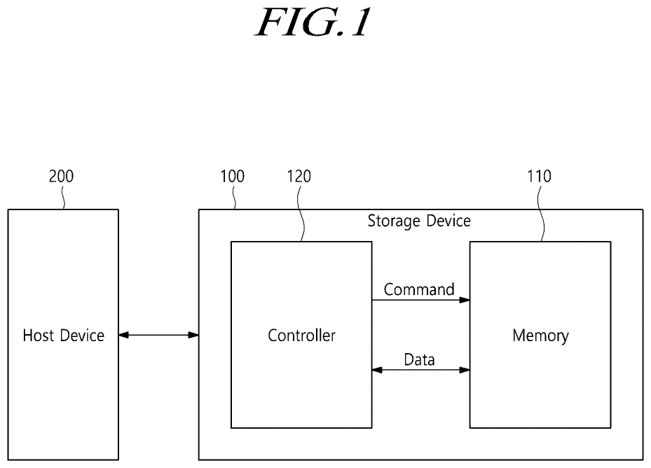

FIG. 1 is a view illustrating a schematic configuration of a storage device 100 according to embodiments of the present disclosure.

Referring to FIG. 1, the storage device 100 may include at least one memory 110. The storage device 100 may include a controller 120 that controls the operation of at least one memory 110. In this disclosure, the storage device 100 may be referred to as an electronic device. In some cases, a device including each of the memory 110 or the controller 120 included in the storage device 100 may be referred to as an electronic device.

The memory 110 may be a volatile memory such as DRAM, SDRAM, DDR SDRAM, and LPDDR SDRAM, but embodiments of the present disclosure are not limited thereto.

The memory 110 may be a nonvolatile memory such as a NAND flash memory, a three-dimensional (3D) NAND flash memory, or a NOR flash memory. In some cases, a portion of the memory 110 included in the storage device 100 may be volatile memory, and another portion thereof may be non-volatile memory.

The memory 110 may be one of various types of memories such as resistive RAM, phase change memory, magnetoresistive memory, ferroelectric memory, or spin injection magnetization inversion memory. Further, the memory 110 may be a processing-in-memory including an arithmetic function or a data processing function, in some cases. In this disclosure, the memory 110 may be referred to as a memory device.

The memory 110 may include a plurality of storage blocks or storage areas. Each of the plurality of storage blocks may include a plurality of memory cells. The plurality of storage blocks may be divided into a plurality of banks, which are units controlled by the controller 120, and each of the plurality of storage blocks may correspond to a bank.

The controller 120 may receive a command from the outside (e.g., an external host device 200) and control the operation of the memory 110 based on the received command. In some cases, the controller 120 may control the operation of the memory 110 based on a command generated therein.

The controller 120 may transmit, to the memory 110, a command for controlling the operation of the memory 110.

The controller 120 may control an operation of writing data to the memory 110. The controller 120 may control an operation of reading data written to the memory 110. Data may be transmitted and received between the controller 120 and the memory 110 according to a write operation or a read operation.

The controller 120 may control an operation (e.g., a refresh operation or a patrol scrub operation) for preserving the data written to the memory 110 or an erase operation according to the type of the memory 110.

The controller 120 may control the operation of the memory 110 based on a command received from the host device 200.

The host device 200 may be, e.g., a computer, an ultra-mobile PC (UMPC), a workstation, a personal digital assistant (PDA), a tablet, a mobile phone, a smartphone, an e-book, a portable multimedia player (PMP), a portable game console, a navigation device, a black box, a digital camera, a digital camera, a digital multimedia broadcasting (DMB) player, a smart television, a digital voice recorder, a digital voice player, a digital video recorder, a digital video player, storage constituting a data center, one of various electronic devices constituting a telematics network, a radio frequency identification (RFID) device, and a moving device (e.g., a vehicle, robot, or drone) capable of driving under human control or autonomous driving. Alternatively, the host device 200 may be a virtual/augmented reality device that provides two-dimensional (2D) or three-dimensional (3D) virtual reality images or augmented reality images. The host device 200 may be any of various electronic devices that require the storage device 100 capable of storing data.

The host device 200 may include at least one operating system. The operating system may generally manage and control the functions and operations of the host device 200, and may control mutual operations between the host device 200 and the storage device 100. The operating system may be divided into a general operating system and a mobile operating system according to the mobility of host device 200.

The host device 200 and the storage device 100 together may be referred to as a computing device or computing system.

The storage device 100 may be positioned adjacent to the host device 200 and may operate under the control of the host device 200. Alternatively, the host device 200 may remotely access the storage device 100 and use the storage device 100 for data processing.

In such a case, the host device 200 may additionally utilize a remotely positioned storage device 100 in addition to the adjacent storage device 100. The remotely positioned storage device 100 may, in some cases, be utilized by a plurality of host devices 200. The storage device 100 may allocate a storage area for each host device 200 or manage it to be shared by two or more host devices 200 and provide a storage area to the host device 200.

The controller 120 and the host device 200 may be devices separated from each other. In some cases, the controller 120 and the host device 200 may be integrated and implemented as one device, or some components or functions of the controller 120 may be implemented to be included in the host device 200. Hereinafter, for convenience, an example is described in which the controller 120 and the host device 200 are separated from each other.

The controller 120 may communicate with the host device 200 and control the memory 110.

The controller 120 may include a configuration for communicating with the host device 200. The controller 120 may include a configuration that communicates with the memory 110 and controls the memory 110.

The controller 120 may be implemented as a single chip, or may be implemented in a form in which a plurality of chiplets are packaged. When the controller 120 is implemented with a plurality of chiplets, each of the plurality of chiplets may be functionally divided or may be divided according to the memory 110 to be controlled.

The controller 120 may include, e.g., a host interface and a memory interface.

The host interface may perform communication between the controller 120 and the host device 200. The host interface may be, e.g., a compute express link (CXL) interface. The host device 200 may be set as a CXL root port, and the storage device 100 may be set as a CXL endpoint. Since the host device 200 communicates with the storage device 100 through the CXL interface, a low-delay, high-bandwidth access environment may be implemented in a structure of communicating with the high-capacity storage device 100.

In some cases, the host interface may be one of various other interfaces other than the CXL interface.

For example, the host interface may be at least one of various communication interfaces or standards such as a universal serial bus (USB) protocol, a multimedia card (MMC) protocol, a peripheral component interconnection (PCI) protocol, a PCI-express (PCI-e or PCIe) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, but embodiments of the disclosure are not limited thereto.

The memory interface may communicate with the memory 110. The memory interface may include a configuration that performs a function of controlling or managing the operation of the memory 110. In some cases, the memory interface refers to a physical layer communicating with the memory 110, and a configuration for controlling and managing the memory 110 may be disposed separately from the memory interface.

The memory 110 may operate under the control of the controller 120 and may include various circuits for performing the operation.

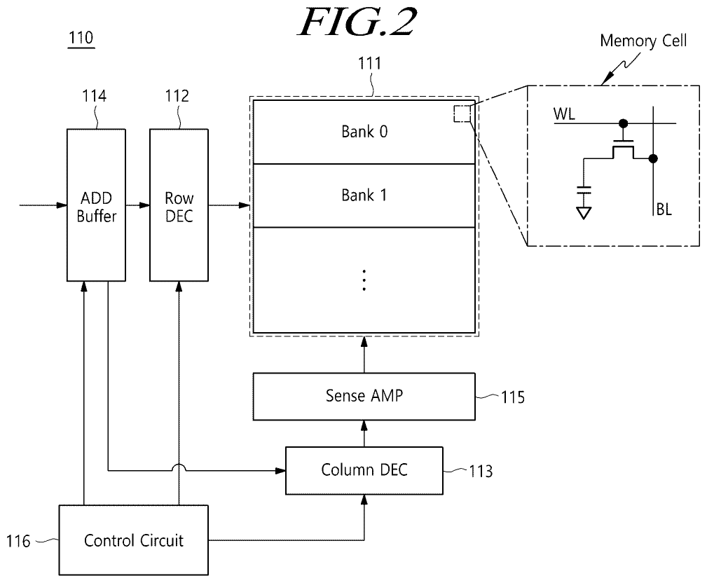

FIG. 2 is a view illustrating a schematic configuration of the memory 110 according to embodiments of the present disclosure.

Referring to FIG. 2, the memory 110 may include a memory cell array 111 including a plurality of memory cells. The memory cell array 111 may be divided into a plurality of banks, which are units controlled by the controller 120. The controller 120 may control the memory cell array 111 on a per-bank basis or on a per-bank group basis. The bank group includes two or more banks.

The memory cell array 111 may include a plurality of word lines WL, a plurality of bit lines BL, and a plurality of memory cells. Each of the plurality of memory cells may be positioned in an area where a word line WL and a bit line BL cross. Each of the plurality of memory cells may include circuit elements, such as a transistor and a capacitor.

The memory cell may be driven by the word line WL. Data may be written to the memory cell or data written to the memory cell may be read through the bit line BL.

The memory 110 may include a row decoder (DEC) 112 that indicates a word line WL to be operated on among a plurality of word lines WL. The memory 110 may include a column decoder (DEC) 113 that indicates a bit line BL to be operated on among a plurality of bit lines BL.

The memory 110 may include an address (ADD) buffer 114 that stores an address received from the outside (e.g., the controller 120 of FIG. 1). The memory 110 may include a control circuit 116 that controls the above-described row decoder 112, column decoder 113, and address buffer 114. The control circuit (or processor) 116 may control the overall operation of the memory 110.

The address buffer 114 may receive information about the address to be operated on through at least one address bit. The address buffer 114 may transfer the received address bits to the row decoder 112 and the column decoder 113.

Each of the row decoder 112 and the column decoder 113 may convert the address bit to designate and drive the word line WL and the bit line BL to be operated.

The memory 110 may include a sense amplifier (AMP) 115 for amplifying read data during a read operation through the bit line BL. The sense amplifier 115 may be positioned to correspond to the entire memory cell array 111, or may be positioned to correspond to each bank constituting the memory cell array 111.

If a voltage change according to the charge stored in the capacitor of the memory cell is detected through the bit line BL during the read operation, the sense amplifier 115 may perform an operation of amplifying the amount of the detected voltage change.

For example, the word line WL may be driven in a state in which a reference voltage is applied to the bit line BL, and the voltage of the bit line BL may vary according to the state of the capacitor of the memory cell. The voltage of the bit line BL may increase or decrease according to the state of the capacitor. The voltage change may be amplified by the sense amplifier 115 to read data of the memory cell through the bit line BL.

The memory 110 may include a data buffer in which data amplified by the sense amplifier 115 is temporarily stored, or a read and write circuit that controls a read operation and a write operation of data.

Further, embodiments of the present disclosure may enhance the performance of the read operation by adjusting the voltage applied to the word line WL for data read according to the state of the memory 110.

In this case, even when the magnitude of the voltage change initially detected by the sense amplifier 115 is set to be small, the accuracy of the read operation may be increased, and thus the capacitance (or magnitude) of the capacitor included in the memory cell may be reduced.

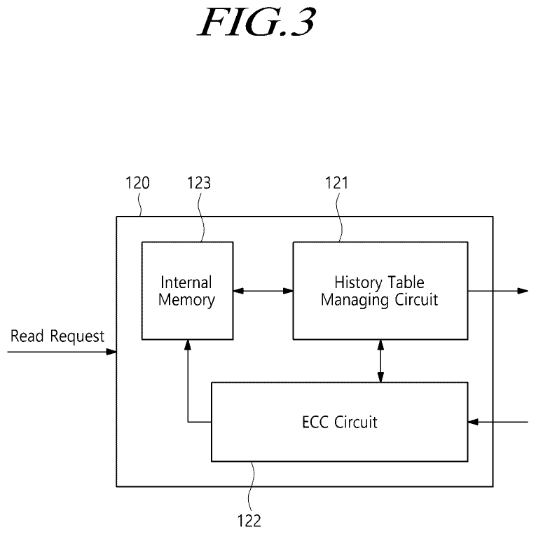

FIG. 3 is a view illustrating a schematic configuration of a controller 120 according to embodiments of the present disclosure.

Referring to FIG. 3, the controller 120 may include a history table managing circuit 121 that manages a read voltage for a read operation on the memory 110.

The read voltage may refer to a voltage applied to the word line WL of the memory cell array 111 or a voltage used to generate the voltage applied to the word line WL during a read operation.

The controller 120 may include an error correction code circuit (ECC circuit) 122 that detects an error in the data read from the memory 110 and performs an operation of correcting the detected error.

The error correction circuit 122 may detect, e.g., an error in data read from the memory 110 and provide information about the bit where the error has occurred. Information about the bit where an error has occurred may be referred to as fail bit information, and fail bit information may mean the number or ratio of fail bits.

The controller 120 may include an internal memory 123 for storing fail bit information and read voltage information. The internal memory 123 may be a non-volatile memory. In this disclosure, the memory 110 positioned outside the controller 120 may be referred to as an external memory. The internal memory 123 may be a non-volatile memory, and the external memory may be a volatile memory.

The controller 120 may adjust the level of the read voltage for the read operation on the memory 110 and control the read operation on the memory 110 based on the fail bit information detected by the error correction circuit 122 and the information about the read voltage managed by the history table managing circuit 121.

For example, the history table managing circuit 121 may manage fail bit information generated during the read operation on the memory 110 through the internal memory 123. The history table managing circuit 121 may manage read voltage information used during the read operation on the memory 110 through the internal memory 123.

The history table managing circuit 121 may manage the above-described information in the form of at least one history table. In some embodiments, the history table may be included in the internal memory 123.

For example, the history table managing circuit 121 may manage a fail bit history table including fail bit information corresponding to the storage area included in the memory 110. The history table managing circuit 121 may manage a voltage history table including read voltage information corresponding to the storage area.

The fail bit history table and the voltage history table may be managed separately, or in some cases, may be integrated and managed. Further, the tables may be managed as one of various forms capable of managing fail bit information and read voltage information for each storage area of the memory 110.

The storage area in which fail bit information and read voltage information are managed may correspond to, e.g., a bank. Alternatively, it may correspond to a bank group including two or more banks.

The history table managing circuit 121 may manage fail bit information and read voltage information corresponding to each of the plurality of banks or each of the plurality of bank groups included in the memory 110 and adjust the read voltage if necessary.

For example, the history table managing circuit 121 may change the level value indicating the read voltage when the number or ratio of fail bits or the variation width thereof according to the fail bit information detected by the error correction circuit 122 is greater than or equal to a preset value.

Alternatively, the history table managing circuit 121 is managed with it divided into a plurality of ranges of fail bit information, and the level value may be changed according to the range in which fail bit information is included.

For example, the plurality of ranges of fail bit information may include a first range, a second range, and a third range. When the fail bit information is included in the first range, the level value indicating the read voltage set as default may be 0. And when the fail bit information is included in the second range or the third range, it is necessary to adjust the read voltage according the range of the fail bit information, and the level value may be changed to 1 or 2.

When the number or ratio of fail bits according to fail bit information increases by a predetermined level or more, the history table managing circuit 121 may change a previously set level value to a level value indicating a higher read voltage. Alternatively, the history table managing circuit 121 may change the previously set level value to the level value indicating the higher read voltage if the variation width of the number or ratio of fail bits is greater than a predetermined level.

In some cases, the history table managing circuit 121 may manage the number, ratio, or range of fail bits corresponding to the level value differently according to the use period of the memory 110.

For example, the history table managing circuit 121 may change the level value using a different threshold according to the use period of the memory 110. For example, when the use period of the memory 110 is short (less than a predetermined level), if the number of fail bits is greater than or equal to a first threshold, the history table managing circuit 121 may increase the level value. When the use period of the memory 110 is greater than or equal to a predetermined level, if the number of fail bits is greater than or equal to a second threshold, the history table managing circuit 121 may increase the level value. The second threshold may be greater than the first threshold. Since deterioration due to an increase in the read voltage may be accelerated as the use period of the memory 110 increases, the threshold that is a reference for increasing the level value may be set to be high according to the use period of the memory 110.

As such, the history table managing circuit 121 may manage the level value while varying the fail bit, which is a reference for changing the level value based on the use period of the memory 110 or the number of writes to the memory cell.

If the fail bit for the storage area increases, the level value may be changed to increase the read voltage for the storage area. Further, in some cases, the level value may be changed to decrease the read voltage when the fail bits decrease.

Since the level value is changed according to the fail bit information, the read voltage may be changed to an appropriate level voltage and managed according to the state of the memory 110 or each storage area.

The history table managing circuit 121 may transmit the changed level value to the memory 110.

The history table managing circuit 121 may transmit the level value to the memory 110 through a separate command from the read command transmitted to the memory 110 for the read operation on the memory 110. Alternatively, in some cases, the history table managing circuit 121 may transmit the level value to the memory 110 using at least a portion of the bits transmitted with the read command, or the read command.

If the level value is transmitted by the history table managing circuit 121, the memory 110 may adjust the read voltage for the read operation for each of the plurality of banks or the plurality of bank groups based on the level value. In some cases, the memory 110 may adjust the read voltage for each memory row included in the bank.

When a read request is received from the outside, the history table managing circuit 121 may identify the history table and transmit the level value to the memory 110. The read request may mean a read command transmitted by the host device 200.

When the read request is received, the history table managing circuit 121 may identify the level value corresponding to the storage area to be read among the level values stored in the history table based on the address according to the read request. The history table managing circuit 121 may transmit the identified level value to the memory 110 and then transmit a read command to the memory 110. In some embodiments, the level value indicates a read voltage for a read operation.

As such, the history table managing circuit 121 may transmit the level value when transmitting the read command according to the read request. Further, the history table managing circuit 121 may update the level value included in the history table according to the fail bit information detected during the read operation and transmit the updated level value to the memory 110. The read operation for the same storage area may be performed again based on the level value transmitted to the memory 110.

The history table managing circuit 121 may transmit the level value to memory 110 in various ways.

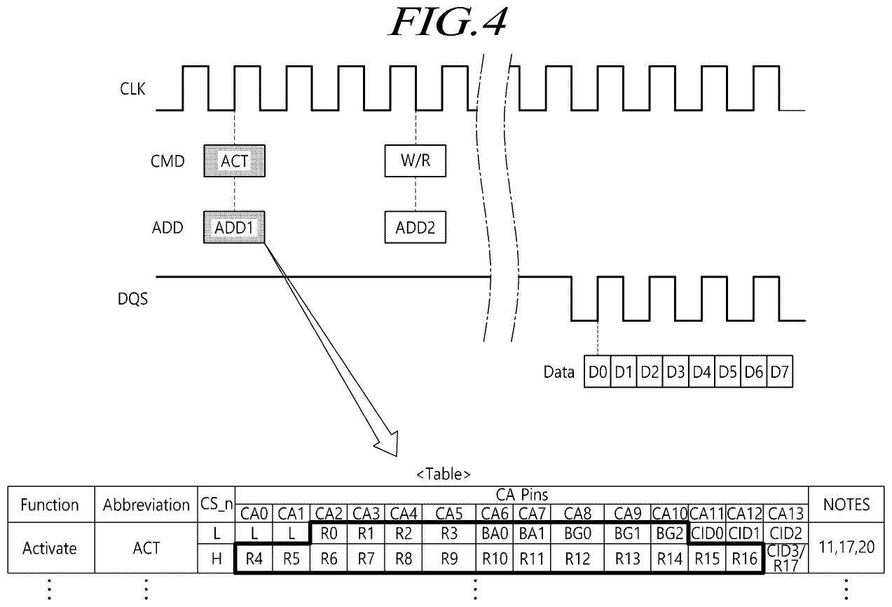

FIG. 4 is a view illustrating an operation method of a controller 120 according to embodiments of the present disclosure.

Referring to FIG. 4, a method in which the controller 120 transmits the level value for the read voltage to the memory 110 is illustrated.

The controller 120 may transmit, to the memory 110, information about a command CMD and an address ADD according to a clock signal CLK.

The controller 120 may transmit, e.g., an active command ACT to the memory 110. The controller 120 may transmit a first address bit ADD1 to the memory 110 after transmitting the active command ACT or according to the active command ACT.

The controller 120 may transmit a write command or a read command W/R to the memory 110 after transmitting the active command ACT. After the write command or the read command W/R is transmitted, data may be transmitted and received between the controller 120 and the memory 110. When the data is transmitted, a data pin strobe signal (DQS) may be transmitted between the controller 120 and the memory 110. The data pin strobe signal (DQS) may indicate a start point and an end point of a transmission of the data.

In an example in which the controller 120 transmits a read command, the controller 120 may transmit a second address bit ADD2 to the memory 110 after transmitting the read command or according to the read command.

The active command ACT and the first address bit ADD1 may be transmitted to the memory 110 in a first period by the controller 120. The read command and the second address bit ADD2 may be transmitted to the memory 110 in a second period by the controller 120. The second period may be a period after the first period.

The controller 120 may transmit the level value to the memory 110 through, e.g., the active command ACT. The controller 120 may transmit the level value to the memory 110 using at least a portion of the first address bit ADD1 transmitted according to the active command ACT.

The first address bit ADD1 may indicate, e.g., a row address to be operated. The second address bit ADD2 may indicate a column address to be operated.

Among the bits included in the first address bit ADD1, BA0, BA1, etc. may indicate the bank address. BG0, BG1, BG2, etc. included in the first address bit ADD1 may indicate the bank group address. Among the bits included in the first address bit ADD1, R0 to R16 may indicate the row address.

The level value may be transmitted to the memory 110 through at least some bits that are not used to indicate the address among the bits included in the first address bit ADD1.

For example, the level value may be transmitted through a bit other than the bit used for row address indication among R0 to R16.

In some cases, the level value may be transmitted to the memory 110 using a bit not used for address indication among other bits included in the first address bit ADD1.

Further, the level value may be transmitted to the memory 110 through a command other than the active command ACT or a data pattern.

For example, the level value may be transmitted to the memory 110 through a mode register command for mode setting of the memory 110.

Alternatively, the level value may be transmitted to the memory 110 through a data pattern transmitted before or after the active command ACT is transmitted. For example, the number of data patterns transmitted before or after transmission of the active command ACT may indicate the level value.

As such, fail bit information for each storage area of the memory 110 may be managed by the controller 120, and the level value for adjusting the read voltage may be easily transferred to the memory 110 according to the fail bit information.

The memory 110 may perform the read operation by adjusting the read voltage for the read operation based on the level value received from the controller 120.

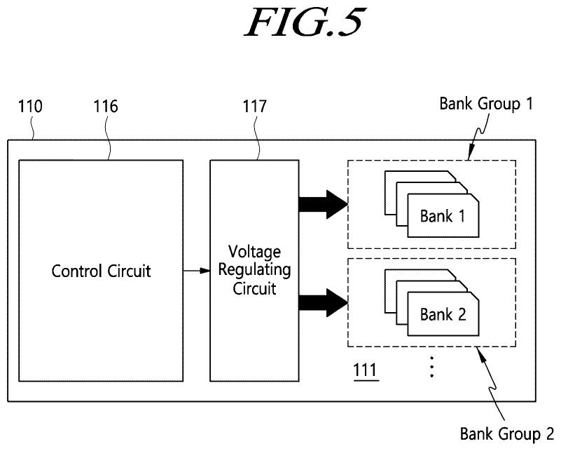

FIG. 5 is a view illustrating a configuration for controlling a read voltage in a memory 110 according to embodiments of the present disclosure.

Referring to FIG. 5, the memory cell array 111 included in the memory 110 may be divided into a plurality of bank groups. Each of the plurality of bank groups may include at least one bank. FIG. 5 shows the memory 110 includes a first bank group Bank Group 1 including at least one first bank Bank 1 and a second bank group Bank Group 2 including at least one second bank Bank 2.

The memory 110 may include a voltage regulating circuit 117 for supplying a read voltage for at least one read operation of the first bank group and the second bank group. The voltage regulating circuit 117 may be, e.g., one of various regulators including low drop-out (LDO), but the embodiments are not limited thereto.

The memory 110 may include a control circuit 116 for controlling the operations of the first bank group and the second bank group and the operation of the voltage regulating circuit 117.

When the read command is received from the controller 120, the control circuit 116 may control the read operation for the first bank group or the second bank group according to the read command.

The control circuit 116 may control the voltage regulating circuit 117 using the level value received before receiving the read command. The voltage regulating circuit 117 may adjust the level of the read voltage output to the first bank group or the second bank group according to the control signal received from the control circuit 116.

The control circuit 116 may receive the level value through various commands, and may manage the read voltage corresponding to the level value in a separate table.

In some cases, the control circuit 116 may directly receive, from the controller 120, read voltage information corresponding to the level value, but as in the above example, only the level value is received, the read voltage corresponding to the level value is separately managed, and the voltage regulating circuit 117 may be controlled. Since the level of the read voltage is managed by the memory 110, the read voltage may be changed according to the characteristics of the memory 110.

The control circuit 116 may receive the level value through the command received before receiving the read command, for example.

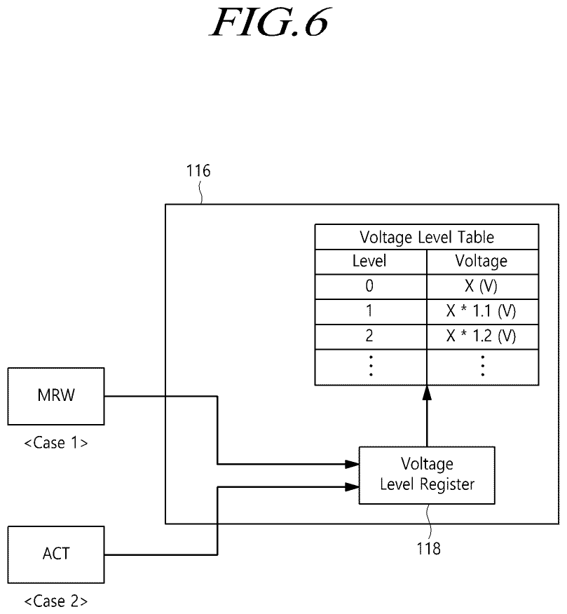

FIG. 6 is a view illustrating an operation method of a control circuit 116 included in the memory 110 of FIG. 5.

Referring to FIG. 6, the control circuit 116 may receive the level value indicating the read voltage for the read operation before the read command is transmitted by the controller 120.

The control circuit 116 may receive the level value through a mode register command, e.g., as shown in Case 1. The controller 120 may transmit, to the memory 110, the level value indicating the read voltage for the read operation of the memory 110 through the mode register write command MRW for setting the mode register of the memory 110.

When the level value through the mode register command is received, the control circuit 116 may set the level of the read voltage in the voltage level register 118 according to the level value. The level of the read voltage may be set for each bank or bank group included in the memory 110.

The control circuit 116 may manage the voltage value corresponding to the level value through the voltage level table.

As shown in FIG. 6, the voltage level table may include level values and voltage values. For example, voltage values respectively corresponding to level values 0, 1, and 2 may be set to X, X*1.1, and X*1.2.

The voltage value X may be a default value of the read voltage supplied during the read operation. If the level value increases, the read voltage may increase by a ratio corresponding to 10%, 20%, and the like. The ratio of the read voltage increased according to the level value may be set differently according to the memory 110. For example, the ratio of increasing the read voltage may be set to a predetermined different width such as 5%, 10%, 15%, etc., or may be set to a width that gradually decreases such as 10, 15%, 17.5%, etc.

The control circuit 116 may identify the level value set in the voltage level register 118, and identify the voltage value corresponding to the level value through the voltage level table. The control circuit 116 may adjust the output of the voltage regulating circuit 117 according to the voltage value.

In another embodiment, the control circuit 116 may receive the level value through the active command ACT as in Case 2. Since the active command ACT may be transmitted before transmission of the read command, the control circuit 116 may receive the level value before receiving the read command.

The control circuit 116 may identify the voltage value corresponding to the received level value in the voltage level table. The control circuit 116 may adjust the output of the voltage regulating circuit 117 according to the identified voltage value.

Since the control circuit 116 may identify the level value and adjust the read voltage through the active command ACT received before receiving the read command, the read voltage may be adjusted for each bank or bank group, or the read voltage may be adjusted for each memory row including the plurality of memory cells included in the bank. The read voltage supplied to drive the word line WL of a memory row included in the same bank may be different from the read voltage supplied to drive the word line WL of another memory row.

The voltage regulating circuit 117 of FIG. 5 may adjust and output the read voltage for the read operation according to the control by the control circuit 116. The voltage regulating circuit 117 may supply the read voltage to the plurality of bank groups. Alternatively, a separate voltage regulating circuit 117 may supply the read voltage to each of the plurality of bank groups.

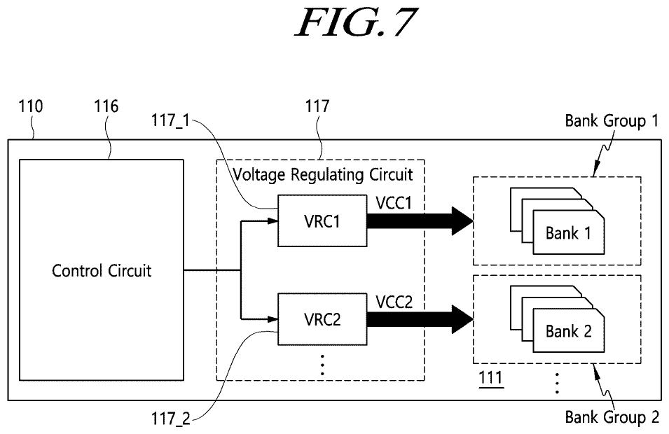

FIG. 7 is a view illustrating an operation method of a voltage regulating circuit 117 included in the memory 110 of FIG. 5.

Referring to FIG. 7, the voltage regulating circuit 117 may include, e.g., a first voltage regulating circuit 117_1 and a second voltage regulating circuit 117_2.

The first voltage regulating circuit 117_1 may output a read voltage to a first bank group Bank Group 1 including at least one first bank Bank 1. The second voltage regulating circuit 117_2 may output a read voltage to a second bank group Bank Group 2 including at least one second bank Bank 2. The read voltages output by the first voltage regulating circuit 117_1 and the second voltage regulating circuit 117_2 may be referred to as VCC1 and VCC2, respectively.

When the read command for the address included in the first bank group is received, the control circuit 116 may identify the voltage value according to the level value and transmit the control signal according to the voltage value to the first voltage regulating circuit 117_1.

The first voltage regulating circuit 117_1 may output the first read voltage to the first bank group according to the control signal by the control circuit 116. The first read voltage may be supplied to the word line WL of the memory cell array 111 included in the first bank group, and the read operation therefore may be performed.

When the read command for the address included in the second bank group is received, the control circuit 116 may identify the voltage value according to the level value and transmit the control signal according to the voltage value to the second voltage regulating circuit 117_2.

The second voltage regulating circuit 117_2 may output the second read voltage to the second bank group according to the control signal by the control circuit 116. The second read voltage may be supplied to the word line WL of the memory cell array 111 included in the second bank group, and the read operation therefore may be performed.

As described above, since the read voltage is adjusted and output according to the level value, the read voltages supplied to the first bank group and the second bank group may be different from each other. For example, the first read voltage may be different from the second read voltage. The read voltage supplied to the bank group having a higher fail bit detected by the controller 120, among the first bank group and the second bank group, may be higher.

By adjusting the read voltage, the size of the voltage margin initially detected by the sense amplifier 115 of FIG. 2 during the read operation may increase, and the accuracy of the read operation may be enhanced.

Additionally, the memory 110 may enhance the accuracy of the read operation by adjusting the read voltage according to the fail bit of the bank group, and enhance the performance or life of the memory 110 by adjusting the cycle of the refresh operation according to the change in the read voltage.

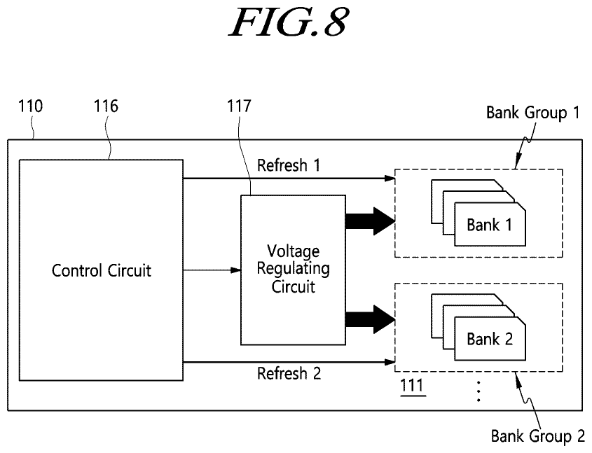

FIG. 8 is a view illustrating a refresh operation of the memory 110 of FIG. 5.

Referring to FIG. 8, the control circuit 116 may adjust a read voltage for a read operation for a first bank group Bank Group 1 and a second bank group Bank Group 2 according to the level value received from the controller 120.

For example, the read operation for the first bank group may be performed by the first read voltage. The read operation for the second bank group may be performed by the second read voltage.

When the first read voltage and the second read voltage are different, the control circuit 116 may differently control the cycle of the refresh operation for the first bank group and the cycle of the refresh operation for the second bank group.

For example, when the first read voltage is greater than the second read voltage, the control circuit 116 may set the first refresh cycle for the refresh operation for the first bank group to be less than the second refresh cycle for the second bank group.

The number of refresh operations performed for the first bank group during a predetermined period may be greater than the number of refresh operations performed for the second bank group.

When the first read voltage is greater than the second read voltage, the degree of deterioration of the first bank group may be regarded as greater than the degree of deterioration of the second bank group, and thus the performance of preserving data written to the first bank group may be maintained by increasing the number of refresh operations for the first bank group.

In another embodiment, when the first read voltage is greater than the second read voltage, the control circuit 116 may set the first refresh period for the refresh operation for the first bank group to be greater than the second refresh period for the refresh operation for the second bank group.

The number of refresh operations performed for the first bank group during a predetermined period may be less than the number of refresh operations performed for the second bank group.

When the first read voltage is greater than the second read voltage, the degree of deterioration of the first bank group may be regarded as greater than the degree of deterioration of the second bank group, and thus it is possible to prevent deterioration of the first bank group from being accelerated by reducing the number of refresh operations for the first bank group.

As described above, since embodiments of the present disclosure perform the read operation by adjusting the read voltage according to the fail bit for each bank or bank group to be the target of the read operation, it is possible to reduce the occurrence of an error in the read operation due to a change in the characteristics or use of the memory 110 and enhance the performance of the read operation.

Further, the performance or life of the memory 110 may be enhanced by adjusting the cycle of the operation performed on the memory cell array 111 such as a refresh operation according to changes in the read voltage.

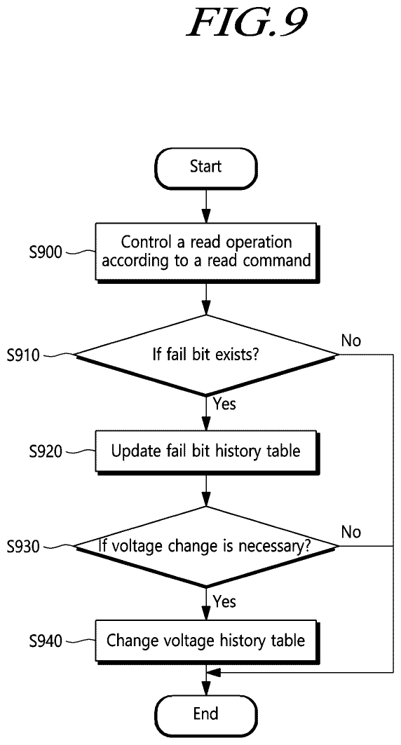

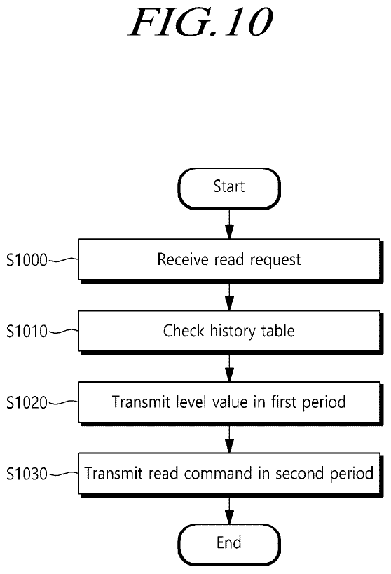

FIGS. 9 and 10 are flowcharts illustrating a process of an operation method of a controller 120 according to embodiments of the present disclosure. FIG. 9 illustrates a method in which a controller 120 manages a level value for a read operation according to an error correction operation. FIG. 10 illustrates a method in which a controller 120 controls a memory 110 according to a read request of a host device 200.

Referring to FIG. 9, the controller 120 may control a read operation on the memory 110 according to a read command (S900). A read operation on the storage area indicated by the address according to the read command may be performed.

The controller 120 may perform an error correction operation on data read from the memory 110. The controller 120 may identify whether a fail bit is detected according to the error correction operation (S910).

The controller 120 may not perform a separate operation when it is determined that the fail bit is not detected. When it is determined that a fail bit is detected, the controller 120 may update the fail bit history table storing fail bit information (S920). The fail bit history table may include, e.g., fail bit information corresponding to the bank group, the bank, or the memory row included in the memory 110.

The controller 120 may identify whether a change in the read voltage is required based on the fail bit history table (S930).

The controller 120 may maintain the voltage history table when it is determined that a change in the read voltage is not required. When it is determined that a change in the read voltage is required, the controller 120 may change the voltage history table (S940). The voltage history table may include, e.g., the level value corresponding to the bank group, the bank, or the memory row included in the memory 110.

When the fail bit reaches a predetermined level, the controller 120 may adjust the level value in a direction of increasing the read voltage. The controller 120 may change the level value indicating the read voltage corresponding to each storage area of the memory 110 according to the fail bit level and prevent performance deterioration of the read operation.

The controller 120 may transmit, to the memory 110, the level value included in the updated or changed voltage history table to control the memory 110 to perform a read operation by the read voltage indicated by the new level value.

Even when a new read request is received from the host device 200, the controller 120 may transmit the level value to the memory 110 based on the voltage history table and control the memory 110 to perform a read operation according to the level value.

For example, referring to FIG. 10, the controller 120 may receive a read request from the host device 200 (S1000). The read request may mean a read command transmitted by the host device 200.

The controller 120 may identify (check) the history table based on the address according to the read request (S1010). The controller 120 may, e.g., identify the above-described voltage history table. The controller 120 may identify the level value corresponding to the storage area including the address according to the read request.

The controller 120 may transmit the identified level value to the memory 110 in the first period (S1020). The controller 120 may transmit the level value to the memory 110 through an active command ACT or a mode register write command MRW.

The controller 120 may transmit a read command indicating a read operation to the memory 110 in the second period (S1030). The second period may be after the first period.

The controller 120 may transmit the level value indicating the read voltage for the read operation for the storage area including the address according to the read command to the memory 110 before transmitting the read command. The controller 120 may control the memory 110 to perform the read operation with the read voltage suitable for the characteristics of the storage area which is the target for the read operation.

Since the read voltage may be adjusted according to characteristics or changes in the characteristics of the storage area of the memory 110 to perform the read operation, it is possible to enhance the accuracy of the read operation on the memory 110 to enhance the reliability of the storage device 100 including the memory 110 and the operation performance of the memory 110.

Based on embodiments of the present disclosure described above, the operation delay time of the memory system may be advantageously reduced or minimized. In addition, based on an embodiment of the present disclosure, an overhead occurring in the process of calling a specific function may be advantageously reduced or minimized. Although various embodiments of the present disclosure have been described with particular specifics and varying details for illustrative purposes, those skilled in the art will appreciate that various modifications, additions and substitutions may be made based on what is disclosed or illustrated in this disclosure without departing from the scope of the embodiments of the present disclosure as defined in the following claims. Furthermore, the embodiments may be combined to form additional embodiments.

What is claimed is:

1. An electronic device comprising:
at least one memory including a plurality of bank groups; and
a controller configured to:
update a history table including a level value indicating a read voltage for a read operation on the plurality of bank groups based on fail bit information according to an error correction operation for data read from the at least one memory, and
transmit the level value included in the updated history table to the at least one memory.

2. The electronic device of claim 1, wherein, when a read request is received, the controller identifies the level value included in the history table, transmits an active command including the level value to the at least one memory, and then transmits a read command corresponding to the read request to the at least one memory.

3. The electronic device of claim 1, wherein the controller transmits the level value to the at least one memory through at least some bits included in an active command.

4. The electronic device of claim 1, wherein the controller transmits the level value to the at least one memory through a mode register command.

5. The electronic device of claim 1, wherein the controller transmits the level value to the at least one memory through a data pattern transmitted before or after transmitting an active command.

6. The electronic device of claim 1, wherein the fail bit information includes a number of fail bits or a ratio of the fail bits, and
the controller adjusts the level value according to at least one of the number of fail bits, the ratio of the fail bits, a variation width of the number of the fail bits, or a variation width of the ratio of the fail bits.

7. The electronic device of claim 1, wherein the controller includes a non-volatile memory storing the history table.

8. The electronic device of claim 1, wherein the at least one memory stores a voltage level table including the read voltage corresponding to the level value.

9. The electronic device of claim 8, wherein the at least one memory includes at least one voltage regulating circuit adjusting the read voltage to be output to at least one of the plurality of bank groups, based on the voltage level table.

10. The electronic device of claim 9, wherein the plurality of bank groups includes a first bank group and a second bank group, and
the at least one voltage regulating circuit includes a first voltage adjustment circuit outputting a first read voltage to the first bank group and a second voltage regulating circuit outputting a second read voltage to the second bank group, and wherein the first read voltage is different from the second read voltage.

11. The electronic device of claim 10, wherein a first refresh cycle for the first bank group is different from a second refresh cycle for the second bank group.

12. The electronic device of claim 11, wherein the first read voltage is greater than the second read voltage, and the first refresh cycle is less than the second refresh cycle.

13. The electronic device of claim 9, wherein the at least one voltage regulating circuit outputs the adjusted read voltage to each of at least two memory rows included in one of the plurality of bank groups, wherein a read voltage output to a first memory row is different from a read voltage output to a second memory row.

14. A memory device comprising:
a first bank group including at least one first bank including a plurality of first memory cells;
a second bank group including at least one second bank including a plurality of second memory cells;
at least one voltage regulating circuit configured to output a read voltage to at least one of the first bank group or the second bank group; and
a control circuit configured to receive a first command including a level value from an outside during a first period, receive a second command indicating a read operation during a second period, and adjust the read voltage output by the at least one voltage regulating circuit based on the level value.

15. The memory device of claim 14, wherein the at least one voltage regulating circuit includes a first voltage regulating circuit outputting a first read voltage to the first bank group and a second voltage regulating circuit outputting a second read voltage to the second bank group, and wherein the first read voltage is different from the second read voltage.

16. The memory device of claim 15, wherein the control circuit controls a refresh operation of the first bank group in a first refresh cycle and controls a refresh operation of the second bank group in a second refresh cycle, and wherein the first refresh cycle is different from the second refresh cycle.

17. The memory device of claim 14, wherein the memory device stores a voltage level table including the read voltage corresponding to the level value.

18. The memory device of claim 14, wherein the first command includes an active command or a mode register write command.

19. A controller comprising:
an internal memory storing a history table;
an error correction circuit configured to perform an error correction operation for data read from an external memory; and
a history table managing circuit configured to:
update the history table including a level value indicating a read voltage for a read operation for the external memory based on fail bit information according to the error correction operation, and
transmit the level value included in the updated history table to the external memory.

20. The controller of claim 19, wherein the external memory includes a volatile memory, and the internal memory includes a non-volatile memory.
